(19) United States
(12) Patent Application Publication
(10) Pub. No.: US 2004/0013800 A1
(43) Pub. Date: Jan. 22, 2004

(54) Device and method for feeding a liquid starting material, which has been brought into the gaseous state, into a CVD reactor

(76) Inventors: Gerhard Karl Strauch, Aachen (DE); Johannes Lindner, Aachen (DE); Marcus Schumacher, Kerpen (DE)

Correspondence Address: ST. ONGE STEWARD JOHNSTON & REENS, LLC, 986 BEDFORD STREET, STAMFORD, CT, 06905-5619, US

(21) Appl. No.: 10/442,215

(22) Filed: May 20, 2003

Related U.S. Application Data
(63) Continuation of application No. PCT/EP01/14302, filed on Oct. 27, 2001.

(30) Foreign Application Priority Data
Nov. 20, 2000 (DE) 100 57 491.2

(51) Int. Cl. C23C 16/00

(52) U.S. Cl. 427/248.1; 118/715

(57) ABSTRACT

The invention relates to a method for supplying a CVD reactor with a liquid starting material entering into a gaseous phase, consisting of a nozzle comprising a liquid channel which leads crosswise into a gas flow channel for producing an aerosol which evaporates with heat. The aim of the invention is to improve the dosability of the generic method or device in such a way that the heat from evaporation is subsequently removed from the gas.

This application is a continuation of pending International Patent Application No. PCT/EP01/14302 filed Oct. 27, 2001, which designates the United States and claims priority of pending German Application No. 100 57 491.2, filed Nov. 20, 2000.

### FIELD OF THE INVENTION

The invention relates to a device and a method for feeding a liquid starting material, which has been brought into the gaseous state, into a CVD reactor, having a nozzle, which has a liquid passage opening out transversely into a gas flow passage, in order to form an aerosol which is vaporized by the supply of heat.

A method of this type and a device for carrying out the method are shown, for example, by U.S. Pat. No. 6,110,531. In this case, a venturi nozzle is used to produce a mist. In this case, a plurality of atomizers which each operate using the venturi principle are provided for different types of liquid starting materials. The mist produced by the atomizers is fed through dedicated pipelines to a gasifier, where the mist droplets are brought into the gaseous state by heat being supplied. The supply of heat takes place via contact heat transfer at a surface.

WO 98/31844 likewise shows a device and method for feeding a liquid starting material which has been brought into the gaseous state into a CVD reactor. In this case too, the liquid starting material is firstly atomized and is then brought into contact with a hot surface, so that the mist droplets are vaporized.

U.S. Pat. No. 5,882,416 likewise describes an LDS (Liquid Delivery System), in which the liquid is brought into a gaseous state via the intermediate stage of a droplet mixture.

The devices described above are used to feed gaseous starting materials, for example metallo-organic strontium, barium, titanium, tantalum or bismuth compounds, to a CVD reactor, in which the metal components condense on in particular a monocrystalline surface to form a ferroelectric layer. On account of the low vapor pressure of the liquid starting material, it cannot be transported in the gaseous state without problems. Moreover, the decomposition temperatures of these metallo-organic compounds are low, so that heating the liquid in order to increase the vapor pressure is not suitable. The window between vaporization temperature and decomposition temperature is very small.

The known devices have the drawback that the reproducibility of the metering is highly inadequate. This is due firstly to the very low liquid flow rates of only a few milliliters per minute. Secondly, the supply of vapor cannot be switched off suddenly, since the vaporization takes place at a surface and the aerosol formation is spatially separate from the vaporization. Moreover, the liquid or a liquid solvent in which the metallo-organic compound is dissolved may be vaporized prematurely. This can lead to the nozzles becoming blocked.

The invention is therefore based on the object of providing means of improving the generic method and the generic device with regard to meterability.

The object is achieved by the invention described in the claims.

According to the invention, the method is developed firstly and substantially through the heat of vaporization being extracted exclusively from the gas. The mist droplets of the aerosol are exposed as suddenly as possible to a temperature-controlled gas atmosphere which supplies the required heat of vaporization in order to convert the mist droplets into the gaseous state. The heat is supplied by controlling the temperature of the gas itself, which completes the heat transfer from a heating surface to the aerosol. According to the invention, the mist droplets no longer come into contact with a surface in order to be vaporized at this surface. The temperature of the gas can be controlled using the walls of a vaporization chamber into which the aerosol flows. The chamber is then formed in such a way that the gas stream enters the chamber freely to such an extent that the aerosol has been completely vaporized before the gas stream comes into contact with a chamber wall. As an alternative or in combination with this measure, it is also possible to provide for the temperature of the actual gas flowing through the gas flow passage to be controlled. In this case, a temperature-controlled gas flows passed the liquid passage. There, this gas forms a vacuum in a known way. Therefore, the liquid is entrained by the temperature-controlled gas stream in accordance with the venturi principle and is broken into fine droplets. These mist droplets are then vaporized in the temperature-controlled gas stream, so that substantially only a gaseous starting material is present in the vaporization chamber.

In a variant of the invention, it is provided that the opening of the liquid passage is opened and closed, in particular in pulsed fashion. The opening of the liquid passage is preferably held at a temperature at which the liquid does not decompose, by cooling. The gas stream also flows past the closed opening of the liquid passage. As soon as the liquid passage is opened, the liquid is sucked out of the liquid passage by the in particular temperature-controlled gas stream, is atomized and is then immediately vaporized. For certain applications, it is advantageous if the open times of the opening of the liquid passage, which is only opened in pulsed fashion, last longer than the closed times. The open length and the pulse sequence are set in such a way that the gas stream ahead of the substrate is uniform. In particular a laminar flow is to prevail at that location. According to this variant, the discharge of liquid into the gas stream flowing through the flow passage is switched on and off. This takes place suddenly, so that highly accurate metering is possible using the pulse width or pulse frequency. If, moreover, the heat is supplied not via surface contact but rather via the gas itself, the device also does not have any memory effect.

The device according to the invention preferably has one or more nozzles which are associated with a vaporization chamber in such a manner that the particular gas stream which produces and transports the aerosol and in particular is subject to pilot temperature control flows freely into the vaporization chamber. The vaporization chamber may be wall-heated. However, it is also possible for the gas flowing through the nozzle to be subjected to pilot temperature control by means of a gas heater upstream of the nozzle.

Furthermore, the object on which the invention is based is achieved by the fact that the liquid passage can be opened and closed in pulsed fashion. For this purpose, the liquid passage may preferably be an annular gap. The liquid passage may in this case be in the shape of a cone. A gap wall of this cone-shaped liquid passage may be formed by a frustoconical valve cone. Furthermore, it is preferred if the liquid passage is surrounded by an annular flow passage. This results in a three-dimensional venturi nozzle. The opening of the flow passage may be directed at an imaginary point which lies in the axis of symmetry of the liquid passage. The resulting main direction of the jet corresponds to the axis of symmetry. Furthermore, it is advantageous if a coating chamber directly adjoins the vaporization chamber. In this case, additional valves or the like can be dispensed with. The coating chamber may be separated from the vaporization chamber only by the diverter members which homogenize the gas flow. The atomization and vaporization nozzle then opens quasi-directly into the coating chamber in which there is a substrate which is to be coated. In a preferred configuration of the nozzle, the lafter is water-cooled. The result of this is that the liquid, which when the valve is closed or open is located in a valve chamber disposed in the nozzle, can be kept at a temperature which is below the decomposition temperature of the liquid. The valve cone can then only be heated by the hot gas stream flowing around it when it is in the open position. In its closed position, it is in surface-to-surface contact with the cooled section of the nozzle, so that the heat which is absorbed by the valve cone can immediately be dissipated into the cooled sections. Therefore, to avoid harmful heating of the valve cone it is advantageous if the closed times of the nozzle are longer than the open times and the valve only opens for a few milliseconds.

### BRIEF DESCRIPTION OF DRAWINGS

An exemplary embodiment of the invention is explained below with reference to appended drawings, in which:

FIG. 1 shows the diagrammatic structure of a device according to the invention for carrying out the method according to the invention,

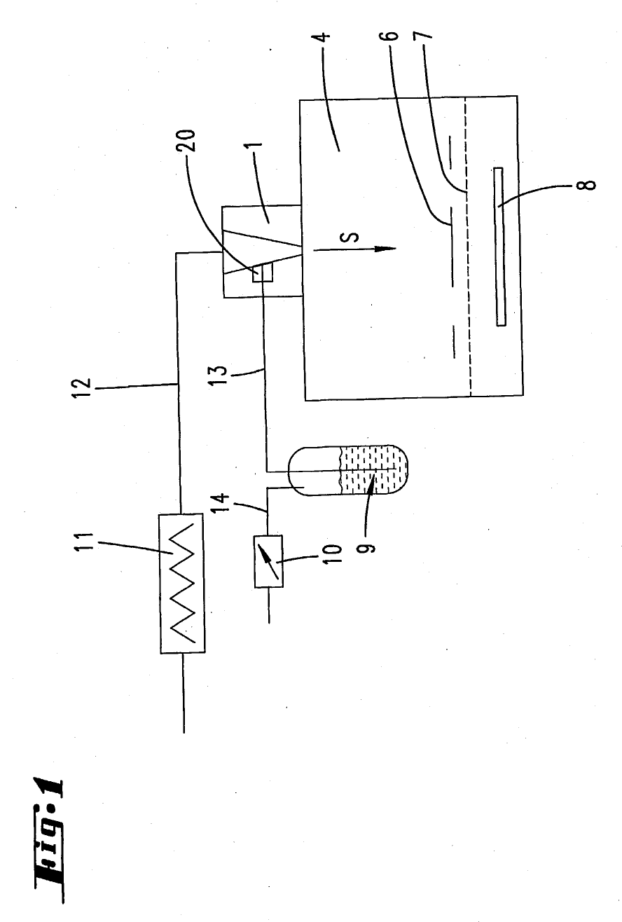

FIG. 2 shows a vaporization chamber, which is likewise only diagrammatically illustrated, with adjacent coating chamber and with a nozzle arrangement associated with the vaporization chamber, and

FIG. 3 shows an enlarged detailed view of a nozzle.

### DETAILED DESCRIPTION OF DRAWINGS

The device in accordance with the exemplary embodiment has a vaporization chamber 4 which has a volume of approximately two liters. The walls of the vaporization chamber 4 are heated, so that the gas located in the vaporization chamber 4 is at a temperature (for example between 200° and 250° C.) which lies between the vaporization temperature and the decomposition temperature. The vaporization chamber 4 is directly adjoined by a coating chamber 5 in which the substrate 8 which is to be coated is located. The vaporization chamber 4 and the coating chamber 5 are separated from one another only by flow-diverting metal sheets 6 or grids 7. The flow-diverting metal sheets 6 or grids 7 are used to produce a gas stream from the vaporization chamber 4 into the coating chamber 5 which is as uniform as possible out of the directed stream S which emerges from the nozzle 1.

A venturi nozzle 1 is positioned at the upper edge of the vaporization chamber 4. A gas feed line 12 opens out into this venturi nozzle 1. In the gas feed line 12 there is a heater 11 which heats the carrier gas flowing through the gas feed line 12 so that it can flow into the nozzle 1 in a temperature-controlled manner. In accordance with the venturi effect, the gas stream passing through the gas feed line 12 produces a vacuum at the opening of the liquid feed line 13, so that the liquid is sucked into the venturi nozzle 1. The opening of the liquid feed line 13 can be opened in pulsed fashion by means of a closure 20.

The liquid feed line connects the nozzle 1 to a liquid tank 9. To convey the liquid out of the liquid tank, a gas can be supplied through the gas line 14 to the tank, in order to displace the liquid from the liquid tank 9. The gas stream flowing through the gas line 14 can be regulated by means of a metering device 10. However, the regulator 10 may simply be a pressure regulator.

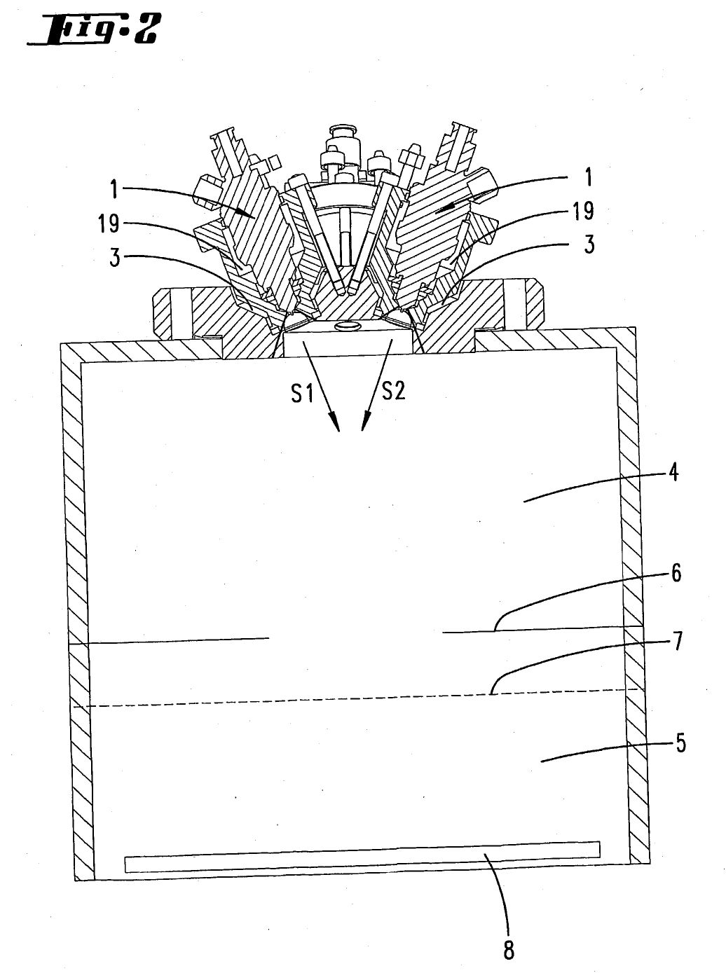

The exemplary embodiment illustrated in FIG. 2 shows a total of two nozzles 1. However, it is also possible for a plurality of nozzles to be associated with one nozzle head. A different metallo-organic component can be fed to the vaporization chamber 4 through each nozzle. The axes of the nozzles 1 intersect one another at an imaginary point. Therefore, if there are a plurality of nozzles, the axes lie on a lateral surface of a cone.

The nozzles have a main jet direction S1, S2, which is in each case directed along the nozzle axis.

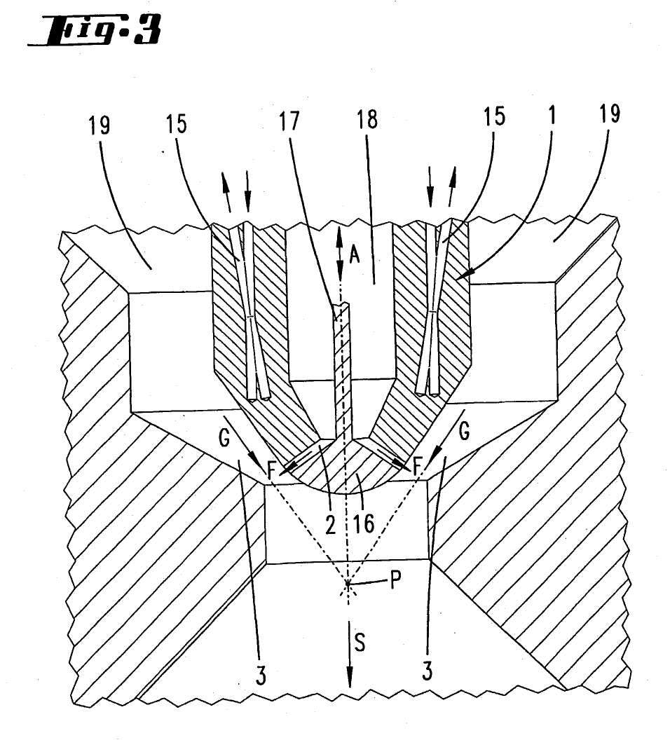

FIG. 3 illustrates the main components of a nozzle 1 on an enlarged scale. The nozzle 1 has a valve chamber 18 in which the liquid is located. A stem 17 which has a valve cone 16 at the end runs through the valve chamber 18. This valve cone 16 is seated with surface-to-surface contact on a conical valve seat. The wall of the nozzle 1, which is also associated with the valve seat, is cooled by means of cooling water flowing through cooling-water passages 15.

The stem 17 can also be moved in the direction of the double arrow A by an electromagnet (not shown), so that the valve cone 16 is lifted off the valve seat. As a result, a conical gap which forms the outlet passage 2 for the liquid is formed. A conical liquid stream F is formed.

The outer contour of the nozzle 1 is frustoconical. The frustoconical lateral surface of the tip of the nozzle 1 is surrounded by a frustoconical annular passage 3. Upstream of the annular flow passage 3 there is an annular chamber 19 which is used for uniform gas distribution of the gas supplied through the gas feed line 12. A conical gas stream G which is directed onto an imaginary point P is formed. The gas stream G runs at right angles to the liquid stream F. The overall result is an overall stream S which runs in the direction of the axis of the nozzle 1. The liquid, which has been broken into fine mist droplets and has been sucked through the gap 2 in accordance with the venturi principle, is present in this gas stream S. The volume of liquid discharged can be metered by varying the opening times of the gap 2.

The gas passing through the flow passage 3 was preheated in the heater 11. The result of this is that the mist droplets are heated rapidly within the gas stream S on account of their large surface area. Vaporization takes place before the gas stream S comes into contact with a hot surface.

If, in a variation of the invention, the gas stream G is not preheated, the atomized liquid can nevertheless be vaporized within the gas phase if the vaporization chamber is heated. The gas located in the vaporization chamber 4, in which the mist is distributed, supplies the required heat in order to convert the mist into the gaseous state.

The gas produced in the vaporization chamber 4 passes through the openings in the flow-diverting metal sheet 6 and through the openings in a following flow-diverting grid 7, in a virtually laminar flow, into the coating chamber 5, where the metallo-organic component, after decomposition, leaves behind a coating on the surface of the substrate 8.

The pulse length of the opening time is in the range from less than one millisecond up to a few milliseconds.

All features disclosed are (inherently) pertinent to the invention. The disclosure content of the associated/appended priority documents (copy of the prior application) is hereby incorporated in its entirety in the disclosure of the application, partly for the purpose of incorporating features of these documents in claims of the present application.

What is claimed is:

1. A method for feeding a liquid starting material, which has been brought into the gaseous state, into a CVD reactor, having a nozzle (1), which has a liquid passage (2) opening out transversely into a gas flow passage (3), in order to form an aerosol which is vaporized by the supply of heat, characterized in that the heat of vaporization is extracted exclusively from the gas.

2. The method according to claim 1 or in particular according thereto, characterized in that the supply of heat is effected by controlling the temperature of the gas.

3. The method according to one or more of the preceding claims or in particular according thereto, characterized in that the temperature of the gas flowing through the gas flow passage (3) is controlled.

4. The method according to one or more of the preceding claims or in particular according thereto, characterized in that the aerosol is transferred by the gas stream (G) flowing through the gas flow passage (3) into a wall-heated vaporization chamber (4), the gas stream (S) which emerges from the nozzle passing freely into the vaporization chamber (4) in such a manner that the aerosol is vaporized before the gas stream (S) comes into contact with a chamber wall.

5. A method for feeding a liquid starting material, which has been brought into the gaseous state, into a CVD reactor, having a nozzle (1), which has a liquid passage (2) opening out transversely into a gas flow passage (3), in order to form an aerosol which is vaporized by the supply of heat, characterized in that the opening of the liquid passage (2) is opened and closed, in particular in pulsed fashion.

6. The method according to claim 5 or in particular according thereto, characterized in that the open times last longer than the closed times.

7. A device for feeding a liquid starting material, which has been brought into the gaseous state, into a CVD reactor, having a nozzle (1), which has a liquid passage (2) which opens out transversely into a flow passage (3), in order to form an aerosol which is vaporized by the supply of heat, characterized in that one or more nozzles (1) of a vaporization chamber (4) are associated in such a manner that the particular gas stream (S) which produces and transports the aerosol and in particular is temperature-controlled, flows freely into the vaporization chamber (4).

8. The device according to claim 7 or in particular according thereto, characterized in that the vaporization chamber (4) is wall-heated.

9. The device according to one or more of the preceding claims or in particular according thereto, characterized by a gas heater (11) upstream of the nozzle (1).

10. A device for feeding a liquid starting material, which has been brought into the gaseous state, into a CVD reactor, having a nozzle (1), which has a liquid passage (2) which opens out transversely into a flow passage (3), in order to form an aerosol which is vaporized by the supply of heat, characterized in that the liquid passage can be opened and closed in pulsed fashion.

11. The device according to claim 10 or in particular according thereto, characterized in that the liquid passage (2) is an annular gap.

12. The device according to one or more of the preceding claims or in particular according thereto, characterized in that the liquid passage (2) is conical in shape and a gap wall of the liquid passage (2) is formed by a frustoconical valve cone (16).

13. The device according to one or more of the preceding claims or in particular according thereto, characterized in that the liquid passage (2) is surrounded by an annular flow passage (3).

14. The device according to one or more of the preceding claims or in particular according thereto, characterized in that the opening of the flow passage (3) is directed at an imaginary point (P) which lies in the axis of symmetry of the liquid passage.

15. The device according to one or more of the preceding claims or in particular according thereto, characterized by a coating chamber (5) which directly adjoins the vaporization chamber (4).

16. The device according to one or more of the preceding claims or in particular according thereto, characterized in that the vaporization chamber (4) and the coating chamber (5) are separated from one another only by the diverter members (6, 7) which homogenize the gas flow.

17. The device according to one or more of the preceding claims or in particular according thereto, characterized in that the nozzle (1) is liquid-cooled, in particular water-cooled.

18. The device according to one or more of the preceding claims or in particular according thereto, characterized in that a plurality of nozzles (1) open out into a common vaporization chamber.

19. The device according to one or more of the preceding claims or in particular according thereto, characterized in that a plurality of vaporization chambers in particular with different chamber temperatures are associated with a common substrate chamber.

20. The device according to one or more of the preceding claims or in particular according thereto, characterized by a plurality of nozzles (1), each for a metallo-organic starting material for deposition as a ferroelectric layer on a substrate, which are directed at a common point.
